(19) United States
(12) Patent Application Publication
(10) Pub. No.: US 2020/0144297 A1
(43) Pub. Date: May 7, 2020

(54) THIN FILM TRANSISTOR AND PREPARATION METHOD THEREOF, AND ARRAY SUBSTRATE AND DISPLAY DEVICE

(71) Applicant: BOE TECHNOLOGY GROUP CO., LTD., BEIJING (CN)

(72) Inventors: Shengguang BAN, Beijing (CN); Zhanfeng CAO, Beijing (CN)

(21) Appl. No.: 16/618,936

(22) PCT Filed: Dec. 4, 2018
(86) PCT No.: PCT/CN2018/119099

§ 371 Date: Dec. 3, 2019

(30) Foreign Application Priority Data
Jan. 2, 2018 (CN) 201810001897.8

(51) Int. Cl. H01L 27/12; H01L 29/786; H01L 29/417; H01L 29/66; H01L 21/768; H01L 23/552

(52) U.S. Cl. CPC H01L 27/124; H01L 29/78675; H01L 23/552; H01L 29/66757; H01L 21/76816; H01L 29/41733

(57) ABSTRACT

The present application discloses a thin film transistor, a method of fabricating the same, an array substrate, and a display device. The thin film transistor comprises: a thin film transistor comprising: a light shielding layer; an active layer; a first insulating layer disposed between the light shielding layer and the active layer; a gate; a second insulating layer disposed between the gate and the active layer; a source electrode coupled to a source region of the active layer; a drain electrode coupled to a drain region of the active layer; and at least one conductive connecting member for connecting the light shielding layer to at least one of the source region and the drain region or at least one of the source electrode and the drain electrode, respectively.

### CROSS-REFERENCE TO RELATED APPLICATIONS

The present application claims priority to Chinese Patent Application No. 201810001897.8 filed on Jan. 2, 2018, which is hereby incorporated by reference in its entirety.

### TECHNICAL FIELD

The present disclosure relates to the field of display technologies, and in particular, to a thin film transistor, a method for fabricating the same, an array substrate, and a display device.

### BACKGROUND

With the development of display technology, low temperature poly-silicon (LTPS) technology has received more and more attentions. Since the LTPS technology can realize high mobility of the device and can implement the Gate Driver over Array (GOA), the display panel based on this technology has a more excellent display effect in terms of aperture ratio, brightness, and reaction speed, as compared with the display panel of the amorphous silicon (a-Si) technology.

### SUMMARY

According to an aspect of the present disclosure, there is provided a thin film transistor comprising: a light shielding layer; an active layer; a first insulating layer disposed between the light shielding layer and the active layer; a gate; a second insulating layer disposed between the gate and the active layer; a source electrode coupled to a source region of the active layer; a drain electrode coupled to a drain region of the active layer; and at least one conductive connecting member for connecting the light shielding layer to at least one of the source region and the drain region, respectively.

In some embodiments, the at least one conductive connecting member comprises two conductive connecting members passing through the first insulating layer to respectively connect the light shielding layer to the source region and the drain region.

In some embodiments, the at least one conductive connecting member comprises two conductive connecting members passing through the first insulating layer to respectively connect the light shielding layer to the source and the drain.

In some embodiments, the at least one conductive connecting member extends through the first insulating layer to connect at least one portion of the light shielding layer to at least one of the source region and the drain region, or to at least one of the source electrode and the drain electrode.

In some embodiments, the light shielding layer comprises amorphous silicon. In some embodiments, the active layer comprises polysilicon.

In some embodiments: the first insulating layer is located over the light shielding layer; the active layer is located over the first insulating layer; the second insulating layer is located over the active layer; the gate is located over the second insulating layer; an interlayer insulating layer is located over the gate; the source electrode and the drain electrode are respectively coupled to the active layer and the light shielding layer through corresponding via holes; the via holes penetrate through the interlayer insulating layer, the second insulating layer, the active layer, and the first insulating layer; and the at least one conductive connecting member comprises two conductive connecting members which are disposed in the via holes, respectively, and form an integral structure with the source and drain electrodes, respectively.

In some embodiments: the first insulating layer is located over the gate; the active layer is located over the first insulating layer; the second insulating layer is located over the active layer; the light shielding layer is located over the second insulating layer; an interlayer insulating layer is located over the light shielding layer; the source electrode and the drain electrode are respectively coupled to the active layer and the light shielding layer through via holes; the via holes penetrate through the interlayer insulating layer, the light shielding layer, and the second insulating layer; the at least one conductive connecting member comprises two conductive connecting members which are disposed in the via holes, respectively, and form an integral structure with the source and drain electrodes, respectively.

In some embodiments, the thin film transistor further comprises: a light transmissive base layer on a side of which the light shielding layer is disposed.

In some embodiments, each of the via holes comprises a first sub via hole and a second sub via hole, the first sub via hole extends through the interlayer insulating layer and the second insulating layer to the active layer, and a lateral dimension of the first sub via hole is greater than a lateral dimension of the second sub via hole.

According to another aspect of the present disclosure, there is provided a method of fabricating a thin film transistor, comprising: providing a multilayer structure comprising a light shielding layer, a first insulating layer, and an active layer, wherein the first insulating layer is disposed between the light shielding layer and the active layer; forming a second insulating layer covering the active layer, and forming a gate over the second insulating layer; forming an interlayer insulating layer over the gate and the second insulating layer; forming a first via hole and a second via hole, each of the first via hole and the second via hole penetrating through the interlayer insulating layer, the second insulating layer, the active layer, and the first insulating layer; forming a source electrode and a drain electrode, the source electrode and the drain electrode, respectively, filling the first via hole and the second via hole and passing through the first via hole and the second via hole to electrically couple to the active layer and the light shielding layer.

In some embodiments, forming the first via hole and the second via hole comprises: forming two first sub via holes penetrating through the interlayer insulating layer and the second insulating layer; and forming two second sub via holes penetrating through the active layer and the first insulating layer.

In some embodiments, a lateral dimension of the first sub via hole is greater than a lateral dimension of the second sub via hole.

In some embodiments, forming the first via hole and the second via hole comprises: forming a patterned mask over the interlayer insulating layer; performing a first etching process with the mask to form two openings penetrating the interlayer insulating layer, the second insulating layer, the active layer, and the first insulating layer such that a part of a surface of the light shielding layer is exposed; reducing the mask to form a reduced mask; and performing a second etching process with the reduced mask such that at least lateral dimensions of parts of the two openings above the active layer are enlarged.

In some embodiments, the light shielding layer comprises amorphous silicon, the active layer comprises polysilicon, and the light shielding layer is configured to shield light to prevent the light from being incident on the active layer.

In some embodiments, providing the multilayer structure including the light shielding layer, the first insulating layer, and the active layer comprises: forming the multilayer structure over a light transmissive base layer.

According to a further aspect of the present disclosure, there is provided a method of fabricating a thin film transistor, comprising: providing a multilayer structure including a gate, a first insulating layer, and an active layer, wherein the first insulating layer is disposed between the gate and the active layer; forming a second insulating layer covering the active layer; forming a light shielding layer over the second insulating layer; forming an interlayer insulating layer over the light shielding layer and the second insulating layer; forming a first via hole and a second via hole, each of the first via hole and the second via hole penetrating through the interlayer insulating layer, the light shielding layer, and the second insulating layer to respectively expose parts of a surface of the active layer; forming a source electrode and a drain electrode, the source electrode and the drain electrode filling the first via hole and the second via hole, respectively, and passing through the first via hole and the second via hole to electrically couple to the active layer and the light shielding layer.

In some embodiments, forming the first via hole and the second via hole comprises: forming a patterned mask over the interlayer insulating layer; performing an etching process with the mask to form the first via hole and the second via hole extending through the interlayer insulating layer, the light shielding layer, and the second insulating layer.

In some embodiments, the light shielding layer comprises amorphous silicon, the active layer comprises polysilicon, and the light shielding layer is configured to shield light to prevent the light from being incident on the active layer.

In some embodiments, providing the multilayer structure including the gate layer, the first insulating layer, and the active layer comprises: forming the multilayer structure over a light transmissive base layer.

According to a still further aspect of the present disclosure, there is provided a array substrate comprising a plurality of thin film transistors according to any embodiment of the present disclosure arranged in an array.

According to an other aspect of the present disclosure, there is provided a display device comprising the array substrate according to any embodiment of the present disclosure.

### BRIEF DESCRIPTION OF THE DRAWINGS

Other aspects, objectives, and advantages of the present application will become more apparent from the detailed description of illustrative embodiments with reference to the accompanying drawings, in which:

FIG. 1 is a schematic structural view of a thin film transistor according to an embodiment of the present application;

FIG. 2A is a schematic structural view of a thin film transistor according to an embodiment of the present application;

FIG. 2B is a schematic structural view of a thin film transistor according to another embodiment of the present application;

FIG. 3 is a schematic structural view of a thin film transistor according to an embodiment of the present application;

FIG. 4 illustrates an exemplary flow chart of a method of fabricating a thin film transistor according to an embodiment of the present application;

FIG. 5A illustrates an exemplary flowchart of a method of fabricating a thin film transistor according to an embodiment of the present application, FIG. 5B illustrates an exemplary flowchart of forming a via hole according to an embodiment of the present application, and FIG. 5C illustrates an exemplary flow chart of forming a via hole according to an embodiment of the present application;

FIG. 6A illustrates an exemplary flowchart of a method of fabricating a thin film transistor according to an embodiment of the present application, and FIG. 6B illustrates an exemplary flowchart of forming a via hole according to an embodiment of the present application; and

FIG. 7 illustrates an exemplary block diagram of a display device according to an embodiment of the present application.

### DETAILED DESCRIPTION OF ILLUSTRATIVE EMBODIMENTS

The present application will be further described in detail below with reference to the accompanying drawings and embodiments. It is to be understood that the specific embodiments described herein are merely illustrative for illustrating the inventions, rather than limiting the inventions. It should also be noted that, for the convenience of description, only those parts related to the inventions are shown in the drawings.

It should be noted that the embodiments of the present application and the features in the embodiments may be combined with each other when appropriate. The present application will be described in detail below with reference to the accompanying drawings.

Technical or scientific terms used in the present disclosure are intended to have the normal meanings to those of ordinary skills in the art. The words “first,” “second,” or the like used in the present disclosure do not denote any priority of order, number, or importance, but are used to distinguish different components. Similarly, the words “comprising” or “including” or variants thereof specify the presence of stated elements or items, but do not preclude the presence or addition of other elements or items. The words “couple” or “connect” and the like are not intended to be limited to physical or mechanical coupling, but may include direct or indirect electrical or signal connections.

In the conventional LTPS process, usually it is necessary to fabricate a light shielding layer to prevent the active layer from being exposed to light and thus affecting the switching performance of the thin film transistor. The inventors of the present application found that the light shielding layer may be affected by the gate voltage when the thin film transistor operates, and induced charges may be generated on the surface of the light shielding layer adjacent to the gate. The light shielding layer is isolated and disposed over the array substrate, resulting in that it is difficult, or requires long time, to eliminate the induced charges. Therefore, the channel region of the active layer of the thin film transistor may be affected, causing the threshold voltage drift of the thin film transistor.

A novel thin film transistor, a method of fabricating the same, an array substrate, and a display device are proposed by the inventors of the present application in view of the above-mentioned drawbacks or deficiencies in the conventional art. According to the embodiments of the present disclosure, the induced charges of the light shielding layer can be effectively eliminated, and the characteristics of the thin film transistor can be improved. In addition, according to the embodiments of the present disclosure, the manufacturing cost can be reduced.

According to an embodiment of the present disclosure, there is provided a thin film transistor which may include: a light shielding layer, a first insulating layer, and an active layer, the first insulating layer being disposed between the light shielding layer and the active layer. The thin film transistor may further include: a second insulating layer; a gate, the second insulating layer being disposed between the gate and the active layer, wherein the active layer may include a source region and a drain region; an interlayer insulating layer; a source electrode and a drain electrode respectively coupled to the source region and the drain region of the active layer. The thin film transistor may further include: at least one conductive connecting member for connecting the light shielding layer to at least one of the source region and the drain region, respectively.

In some embodiments, the at least one conductive connecting member may include two conductive connecting members passing through the first insulating layer to connect the light shielding layer to the source region and the drain region, respectively.

In another embodiment, the at least one conductive connecting member may include two conductive connecting members passing through the first insulating layer to connect the light shielding layer to the source and the drain, respectively.

In some embodiments, the thin film transistor may further include: at least one conductive connecting member extending through the first insulating layer to connect at least one portion of the light shielding layer to at least one of the source region and the drain region, or to at least one of the source electrode and the drain electrode.

Additionally, in some embodiments, the at least one conductive connecting member may include two conductive connecting members that form an integral structure with the source electrode and the drain electrode, respectively. In other words, in some embodiments, the conductive connecting members can respectively be parts of the corresponding source electrode or drain electrode. It should be understood that the present disclosure shall not be limited thereto.

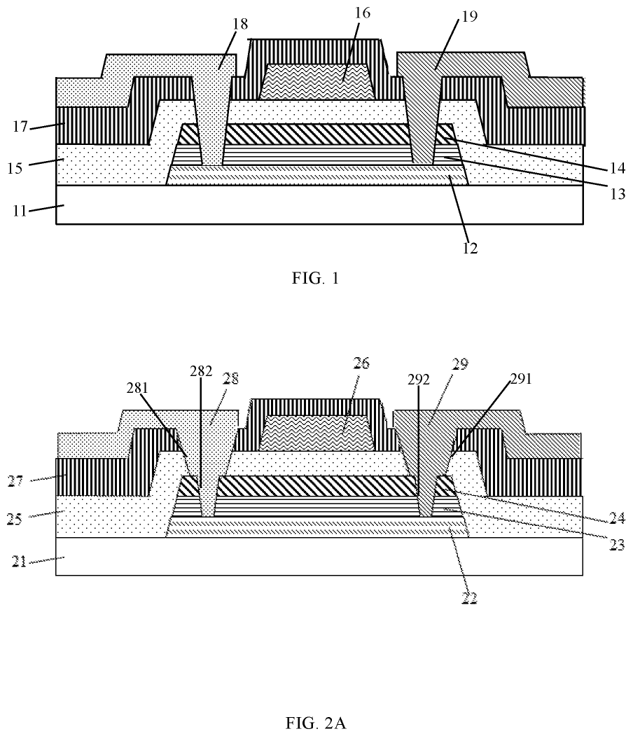

FIG. 1 illustrates a schematic structural view of a thin film transistor according to an embodiment of the present application. The thin film transistor can be used in a display panel (for example but not limited to, a liquid crystal display panel).

As shown in FIG. 1, there is provided a thin film transistor comprising: a light shielding layer 12, a first insulating layer 13, an active layer 14, a second insulating layer 15, a gate 16, an interlayer insulating layer 17, and a source electrode 18 and a drain electrode 19 respectively coupled to the active layer 14. The source electrode 18 and the drain electrode 19 are also coupled to the light shielding layer 12. In this embodiment, the light shielding layer 12, the first insulating layer 13, the active layer 14, the second insulating layer 15, the gate 16, the interlayer insulating layer 17, the source electrode 18 and the drain electrode 19 may each be located over a base layer 11. FIG. 1 illustrates a transistor of a top gate structure. The positional relationship among the layers is not limited to that shown in FIG. 1. In other embodiments, the thin film transistor can also be of a bottom gate structure or other structure. The first insulating layer 13, the second insulating layer 15, and the interlayer insulating layer 17 may each include an insulating material, such as any one of the following: silicon oxide, silicon nitride, a mixture of the two, and the like. In some embodiments, one or more of the first insulating layer 13, the second insulating layer 15, and the interlayer insulating layer 17 may be configured to allow light to pass therethrough.

In some embodiments, the light shielding layer may include amorphous silicon. The active layer may include polysilicon. The light shielding layer may be configured to shield light to prevent light from being incident on the active layer.

In the operation of a conventional thin film transistor (for example, an N-type transistor), after a voltage (for example, a positive voltage) is applied to the gate, a negative charge is induced at a side of the active layer near the gate side, and a positive charge is induced at a side of the active layer away from the gate side. The thickness of the insulating layer between the light shielding layer and the active layer is usually small, so that negative charges may be induced at the side of the light shielding layer adjacent to the active layer side, thereby affecting the charge distribution in the active layer when the thin film transistor operates next time, resulting in that the threshold voltage is negatively offset. The same holds true for P-type transistors, except that the polarity of the induced charges is reversed.

In the embodiments of the present disclosure, since the source/drain electrodes are coupled to the active layer meanwhile being coupled to the light shielding layer, the induced charges of the light shielding layer can be discharged. Thereby, the influence on the thin film transistor by the induced charges of the light shielding layer can be avoided. In addition, the stability of the threshold voltage of the thin film transistor can be improved. Therefore, the performance of the thin film transistor is improved.

In addition, those skilled in the art will readily appreciate that for a MOS transistor, the active region may include a channel formation region, and a source region and a drain region adjacent to the channel formation region, respectively. The channel formation region is located in correspondence with the gate and is used to form a channel therein. When the transistor is operating, the gate voltage makes the conductivity type of some or all of the channel formation region in the active region reversed, thereby forming a channel. The source region corresponds to and is coupled to the source electrode. The drain region corresponds to and is coupled to the drain electrode.

Further, the material of the light shielding layer can be, for example but not limited to, elementary substance of silicon or an oxide semiconductor. Specifically, the elementary substance of silicon may comprise, for example but not limited to, a non-transparent silicon elementary material such as single crystal silicon or amorphous silicon. Specifically, the oxide semiconductor may comprise, for example but not limited to, a non-transparent oxide semiconductor material such as alumina or titanium oxide.

In a particular embodiment, the base layer can comprise a light transmissive substrate such as a glass substrate. In other embodiments, the base layer can include other types of substrates. In addition, the base layer may further include a substrate and other functional layers (such as a buffer layer or the like) over the substrate.

According to the present embodiment, the source/drain electrodes are coupled to the active layer while being coupled to the light shielding layer, thus the potential of the light shielding layer can be relatively stabilized. In addition, it is also possible to make the potentials of at least a portion of the light shielding layer (for example, the portion coupled to the source region or the source electrode and the portion in its vicinity) and a corresponding portion of the active layer are substantially the same or close to each other, therefore the possibility of inducing charges in the light shielding layer can be reduced. Therefore, the stability of the thin film transistor can be further improved.

Further, in the case where the material of the light shielding layer is amorphous silicon, in some embodiments, the source and drain electrodes are coupled to the light shielding layer of amorphous silicon, but the surface thereof in contact with the amorphous silicon layer does not form an ohmic contact. Therefore, no channel is formed in the amorphous silicon. In addition, the resistance of amorphous silicon is generally large. Therefore, the presence of the amorphous silicon light shielding layer does not cause a significant increase in the leakage current of the thin film transistor. After the thin film transistor is turned off, the OFF current can be at the order of E⁻¹² or even lower.

The material of the active layer may comprise polysilicon. In a further embodiment, the first insulating layer is located over the light shielding layer; the active layer is over the first insulating layer; the second insulating layer is over the active layer; the gate is over the second insulating layer; the interlayer insulating layer is located over the gate, and the source electrode and the drain electrode are respectively coupled to the active layer and the light shielding layer through via holes; the via holes penetrate the interlayer insulating layer, the second insulating layer, the active layer and the first insulating layer.

In an embodiment of the present application, the light shielding layer 12, the first insulating layer 13, the active layer 14, the second insulating layer 15, the gate 16, the interlayer insulating layer 17, the source electrode 18 and the drain electrode 19 may be formed in a bottom-to-top stacked positional relationship as shown in FIG. 1, that is, it can be a top gate structure. Via holes (not labeled) penetrate the interlayer insulating layer, the second insulating layer, the active layer, and the first insulating layer. The via holes can have any suitable shapes and sizes. As shown in the figure, portions of the source electrode and the drain electrode fill in the corresponding via holes to form the aforementioned conductive connecting members, respectively. In the example shown in FIG. 1, the at least one conductive connecting member may include two conductive connecting members, which are respectively parts of the source electrode and the drain electrode, and are respectively disposed in respective via holes.

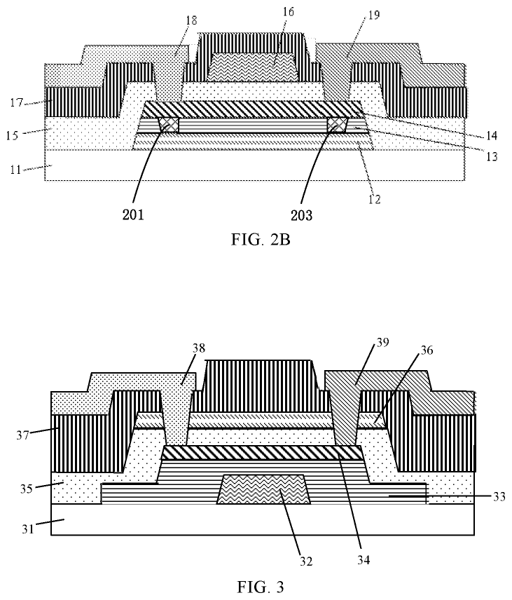

FIG. 2A is a schematic view showing the structure of a thin film transistor according to another embodiment of the present application.

In this embodiment, as shown in FIG. 2A, each via hole 28 (29) can include a first sub via hole 281 (291) and a second sub via hole 282 (292). The first sub via hole 281 (291) penetrates the interlayer insulating layer and the second insulating layer, and the second sub via hole 282 (292) penetrates the active layer and the first insulating layer. According to the present embodiment, each via hole actually includes two sub via holes, which can reduce the process difficulty, while increasing the contact area between the source and drain electrodes and the active layer, and improving the characteristics of the thin film transistor. It will be appreciated that the via hole may include two or more sub via holes.

In some embodiments, the lateral dimension of the first sub via hole is greater than the lateral dimension of the corresponding second sub via hole. Thereby, the contact area of the via hole with the active layer is increased, and the contact resistance with the active layer and bulk resistance of the electrode can be lowered.

FIG. 2B is a schematic view showing the structure of a thin film transistor according to another embodiment of the present application. As shown in FIG. 2B, the thin film transistor may include: a light shielding layer 12; a first insulating layer 13; and an active layer 14, the first insulating layer being disposed between the light shielding layer and the active layer. The thin film transistor may further include: a second insulating layer 15; a gate 16, wherein the second insulating layer is disposed at least between the gate and the active layer, and the active layer may include a source region and a drain region; an interlayer insulating layer 17; a source electrode 18/19 and a drain electrode 19/18 respectively coupled to a source region and a drain region (not indicated by reference numerals in the drawing) of the active layer. The thin film transistor may further include: at least one conductive connecting member 201/203 passing through the first insulating layer to connect at least one portion of the light shielding layer to at least one of the source region and the drain region.

In the embodiment shown in FIG. 2B, two conductive connecting members are shown: a first conductive connecting member 201 and a second conductive connecting member 203. In other embodiments, more or fewer conductive connecting members may be included. In addition, although in the embodiment shown in FIG. 2B the first conductive connecting member 201 and the second conductive connecting member 203 are disposed at positions away from the end faces of the first insulating layer 13, the present disclosure is not limited thereto. For example, the first conductive connecting member 201 and the second conductive connecting member 203 may be disposed at or near ends of the first insulating layer 13. There is no particular limitation on the materials and processes for the first conductive connecting member 201 and the second conductive connecting member 203, as long as they are compatible with the process for forming the thin film transistor. For example, doped polysilicon (Poly-Si) may be employed to form the conductive connecting members where appropriate.

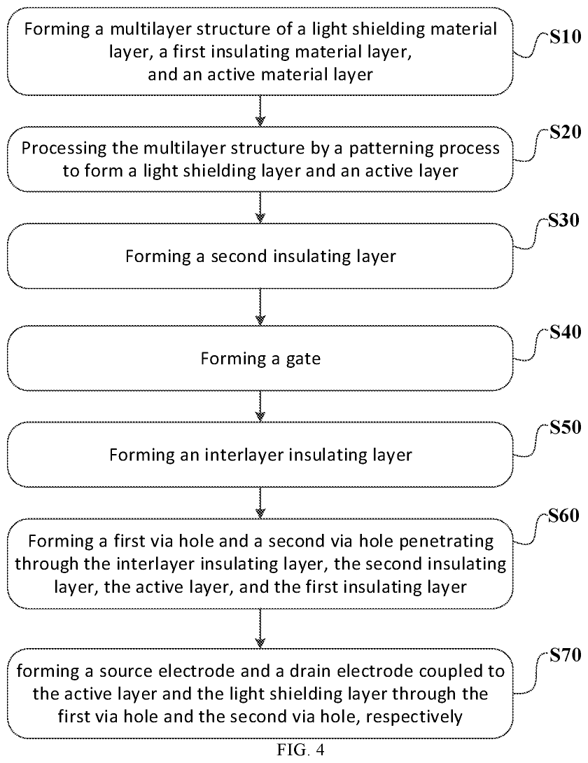

FIG. 3 illustrates a schematic structural view of a thin film transistor according to an embodiment of the present application. As shown in FIG. 3, in this embodiment, the first insulating layer 33 is over the gate 32; the active layer 34 is over the first insulating layer 33; the second insulating layer 35 is over the active layer 34; the light shielding layer 36 is over the second insulating layer 35; the interlayer insulating layer 37 is located over the light shielding layer 36; the source electrode 38 and the drain electrode 39 are respectively coupled to the active layer 34 and the light shielding layer 36 through via holes; the via holes penetrate the interlayer insulating layer 37, the light shielding layer 36, and the second insulating layer 35.

In the embodiment of the present application, the gate 32, the first insulating layer 33, the active layer 34, the second insulating layer 35, the light shielding layer 36, the interlayer insulating layer 37, the source electrode 38 and the drain electrode 39 may be formed to be stacked from bottom to top as shown in FIG. 3. That is, the thin film transistor is of a bottom gate structure. Via hole(s) (not indicated by a reference numeral in the drawing) penetrates the interlayer insulating layer and the second insulating layer. Thereby the via hole exposes a portion of the active layer. The via hole(s) can have any suitable shape and size. As shown in the figure, portions of the source and the drain are filled in the corresponding via holes, as shown in the figure, to form the aforementioned conductive connecting members, respectively. In the example shown in FIG. 3, the at least one conductive connecting member may include two conductive connecting members, which are respectively parts of the source electrode and the drain electrode, and are respectively disposed in corresponding via holes. It will be appreciated that the via hole may include two or more sub via holes.

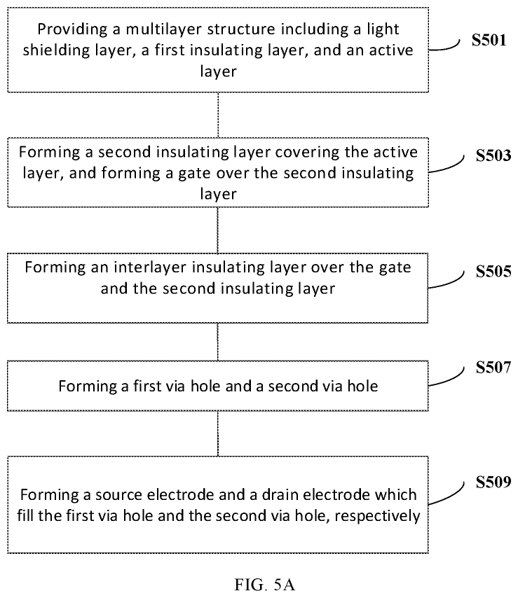

FIG. 4 illustrates a method of fabricating a thin film transistor according to an embodiment of the present application. The method can include one or more of the following steps.

Step S10: forming a multilayer structure of a light shielding material layer, a first insulating material layer, and an active material layer. The light shielding material layer may be formed over a base substrate by a PECVD (Plasma Enhanced Chemical Vapor Deposition) method. Also, the first insulating material layer and the active material layer may be sequentially formed over the light shielding material layer by the PEVCD method.

Step S20: processing the multilayer structure by a patterning process to form a light shielding layer and an active layer. In an example embodiment, the multilayer structure formed in step S10 may be etched by one-time patterning process to form a light shielding layer, a first insulating layer, and an active layer.

Step S30: forming a second insulating layer. In an example embodiment, the second insulating layer can be formed over the active layer using a PECVD method.

Step S40: forming a gate. In an example embodiment, a gate material layer may be formed over the second insulating layer by sputtering, and then be processed by one-time patterning process to form gate.

Step S50: forming an interlayer insulating layer. In an example embodiment, an interlayer insulating layer may be formed over the gate using a PECVD method.

Step S60: forming a first via hole and a second via hole penetrating through the interlayer insulating layer, the second insulating layer, the active layer, and the first insulating layer. In an example embodiment, the first via hole and the second via hole may be formed by one-step etching or may be formed by multi steps of etching. In a specific example, the multi steps of etching may include: forming a first intermediate via hole and a second intermediate via hole penetrating the inter-layer insulating layer, the second insulating layer, the active layer, and the first insulating layer by etching; then widening the holes of the parts of the first intermediate via hole and the second intermediate via hole extending through the interlayer insulating layer and the second insulating layer portion by etching. Thereby, the effect of increasing the contact area between the source and drain electrodes and the active layer can be achieved.

In addition, step S60 may further includes:

after the two first sub via holes through the interlayer insulating layer and the second insulating layer are formed, forming two second sub via holes that penetrate the active layer and the first insulating layer.

Step S70: forming a source electrode and a drain electrode coupled to the active layer and the light shielding layer through the first via hole and the second via hole, respectively.

In the above embodiment, the light shielding layer and the active layer can be formed by one-time patterning process, which reduces the number of the patterning processes and reduces the manufacture cost. In addition, by forming the first via hole and the second via hole extending through the interlayer insulating layer, the second insulating layer, the active layer, and the first insulating layer, the source electrode and the drain electrode are coupled to the light shielding layer, and the induced charges in the light shielding layer can be conducted to external circuit. In addition, in various embodiments, the first via hole and the second via hole that penetrate the interlayer insulating layer, the second insulating layer, the active layer, and the first insulating layer may be formed by etching with one mask formation, thereby simplifying the process, reducing manufacturing costs, and/or increasing production efficiency.

According to embodiments of the present disclosure, the influence of the induced charges of the light shielding layer can be alleviated or eliminated, the stability of the threshold voltage can be improved, and the characteristics of the thin film transistor can be improved.

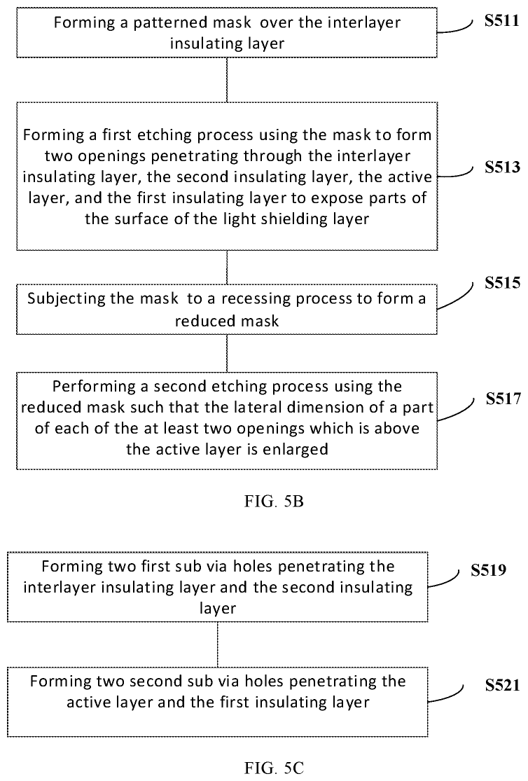

FIG. 5A illustrates an exemplary flow chart of a method of fabricating a thin film transistor in accordance with an embodiment of the present application. As shown in FIG. 5A, according to the method of manufacturing a thin film transistor of this embodiment, in step S501, a multilayer structure including a light shielding layer, a first insulating layer, and an active layer is provided. The first insulating layer is disposed between the light shielding layer and the active layer.

In step S503, a second insulating layer covering the active layer is formed, and a gate is formed over the second insulating layer.

In step S505, an interlayer insulating layer is formed over the gate and the second insulating layer.

In step S507, a first via hole and a second via hole are formed. The first via hole and the second via hole each penetrate the interlayer insulating layer, the second insulating layer, the active layer, and the first insulating layer.

In step S509, a source electrode and a drain electrode are formed. The source electrode and the drain electrode fill the first via hole and the second via hole, respectively. The source electrode and the drain electrode are electrically coupled to the active layer and the light shielding layer through the first via hole and the second via hole.

FIG. 5B illustrates an exemplary flow chart for forming via holes in accordance with an embodiment of the present application. In an embodiment, the first via hole and the second via hole may be formed as follows. As shown in FIG. 5B, in step S511, a patterned mask is formed over the interlayer insulating layer. In step S513, a first etching process is performed using the mask to form two openings penetrating through the interlayer insulating layer, the second insulating layer, the active layer, and the first insulating layer to expose parts of the surface of the light shielding layer. In step S515, the mask is subjected to a recessing process to form a reduced mask. In step S517, a second etching process is performed using the reduced mask such that the lateral dimension of a part of each of the at least two openings which is above the active layer is enlarged (as can be seen from FIG. 2A).

FIG. 5C illustrates an exemplary flow chart for forming via holes in accordance with another embodiment of the present application. In an embodiment, the first via hole and the second via hole may also be formed in the following manner. In step S519, two first sub via holes penetrating the interlayer insulating layer and the second insulating layer are formed. In step S521, two second sub via holes penetrating the active layer and the first insulating layer are formed.

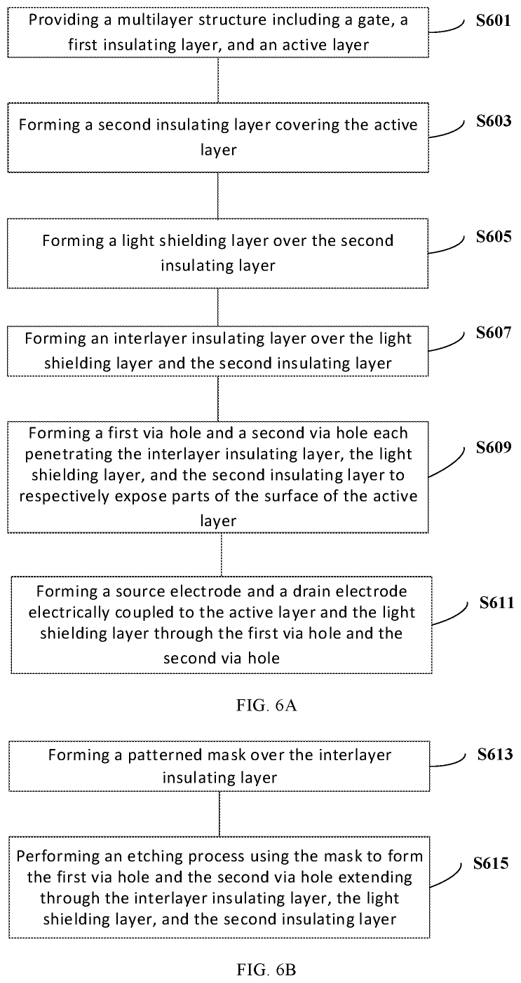

FIG. 6A illustrates an exemplary flow chart of a method of fabricating a thin film transistor in accordance with another embodiment of the present application. As shown in FIG. 6A, in step S601, a multilayer structure including a gate, a first insulating layer, and an active layer is provided. The first insulating layer is disposed between the gate and the active layer. In step S603, a second insulating layer covering the active layer is formed. In step S605, a light shielding layer is formed over the second insulating layer. In step S607, an interlayer insulating layer is formed over the light shielding layer and the second insulating layer. In step S609, a first via hole and a second via hole are formed. The first via hole and the second via hole each penetrate the interlayer insulating layer, the light shielding layer, and the second insulating layer to respectively expose parts of the surface of the active layer. In step S611, a source electrode and a drain electrode are formed. The source electrode and the drain electrode fill the first via hole and the second via hole, respectively. The source electrode and the drain electrode are electrically coupled to the active layer and the light shielding layer through the first via hole and the second via hole.

FIG. 6B illustrates an exemplary flow chart for forming via holes in accordance with an embodiment of the present application. In an embodiment, the first via hole and the second via hole may be formed as follows. As shown in FIG. 6B, in step S613, a patterned mask is formed over the interlayer insulating layer. In step S615, an etching process is performed using the mask to form the first via hole and the second via hole extending through the interlayer insulating layer, the light shielding layer, and the second insulating layer. Those skilled in the art will readily appreciate that different etchants, processes, and the like can be selected for different materials to be etched in the etching process.

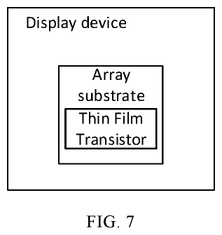

FIG. 7 illustrates an exemplary block diagram of a display device in accordance with an embodiment of the present application. As shown in FIG. 7, according to an embodiment of the present application, there is provided an array substrate including a plurality of thin film transistors according to any embodiment of the present application arranged in an array. Further, according to an embodiment of the present application, there is further provided a display device which includes the array substrate according to the embodiments of the present application.

According to the embodiments of the present application, a novel thin film transistor is provided. By connecting the source electrode and the drain electrode to the light shielding layer, the charge induced in the light shielding layer can be conducted to external circuit, and the influence of the induced charge of the light shielding layer can be alleviated or eliminated, and the stability of the threshold voltage can be improved. According to the embodiments of the present disclosure, the performance of the thin film transistor can be improved.

It should be understood that the boundaries between the above operations/steps are merely illustrative. Multiple operations/steps may be combined into a single operation/step, a single operation/step may be distributed among additional operations/steps, and operations/steps may be performed at least partially overlapping in time. Moreover, alternative embodiments may include multiple instances of a particular operation/step, and the sequence of the operations/steps may be varied in other various embodiments. However, other modifications, changes, and replacements are also possible. Accordingly, the specification and drawings are to be regarded as illustrative, not for limiting.

It is to be understood that the foregoing description is only illustrative of the embodiments of the invention and some applications thereof. Various embodiments of the present disclosure have been described as above, and the foregoing descriptions are merely illustrative and not intended to enumerate all the possible embodiments of the present disclosure; thus, the present disclosure shall not be limited to the specific embodiments disclosed herein. The various embodiments disclosed herein can be arbitrarily combined as appropriate without departing from the spirit and scope of the present disclosure. Many modifications and variations will be apparent to those skilled in the art, and are intended to be embraced in the spirit and scope of the present disclosure. The scopes of the inventions are to be defined by the appended claims.

1. A thin film transistor comprising:
a light shielding layer;
an active layer;
a first insulating layer disposed between the light shielding layer and the active layer;
a gate;
a second insulating layer disposed between the gate and the active layer;
a source electrode coupled to a source region of the active layer;
a drain electrode coupled to a drain region of the active layer; and
at least one conductive connecting member for connecting the light shielding layer to at least one of the source region and the drain region.

2. The thin film transistor according to claim 1, wherein the at least one conductive connecting member comprises two conductive connecting members passing through the first insulating layer to respectively connect the light shielding layer to the source region and the drain region.

3. The thin film transistor of claim 1, wherein the at least one conductive connecting member comprises two conductive connecting members passing through the first insulating layer to respectively connect the light shielding layer to the source region and the drain region.

4. The thin film transistor according to claim 1, wherein the light shielding layer comprises amorphous silicon, and the active layer comprises polysilicon.

5. The thin film transistor according to claim 1, wherein:
the first insulating layer is located over the light shielding layer;
the active layer is located over the first insulating layer;
the second insulating layer is located over the active layer;
the gate is located over the second insulating layer;
an interlayer insulating layer is located over the gate;
the source electrode and the drain electrode are respectively coupled to the active layer and the light shielding layer through corresponding via holes;
the via holes penetrate through the interlayer insulating layer, the second insulating layer, the active layer, and the first insulating layer; and
the at least one conductive connecting member comprises two conductive connecting members which are disposed in the via holes, respectively, and form an integral structure with the source electrode and the drain electrodes, respectively.

6. The thin film transistor according to claim 1, wherein:
the first insulating layer is located over the gate;
the active layer is located over the first insulating layer;
the second insulating layer is located over the active layer;
the light shielding layer is located over the second insulating layer;
an interlayer insulating layer is located over the light shielding layer;
the source electrode and the drain electrode are respectively coupled to the active layer and the light shielding layer through via holes;
the via holes penetrate through the interlayer insulating layer, the light shielding layer, and the second insulating layer;
the at least one conductive connecting member comprises two conductive connecting members which are disposed in the via holes, respectively, and form an integral structure with the source electrode and the drain electrodes, respectively.

7. The thin film transistor of claim 1 further comprising:
a light transmissive base layer on a side of which the light shielding layer is disposed.

8. The thin film transistor of claim 5, wherein:
each of the via holes comprises a first sub via hole and a second sub via hole,
the first sub via hole extends through the interlayer insulating layer and the second insulating layer to the active layer, and
a lateral dimension of the first sub via hole is greater than a lateral dimension of the second sub via hole.

9. A method of fabricating a thin film transistor, comprising:
providing a multilayer structure comprising a light shielding layer, a first insulating layer, and an active layer, wherein the first insulating layer is disposed between the light shielding layer and the active layer;
forming a second insulating layer covering the active layer, and forming a gate over the second insulating layer;
forming an interlayer insulating layer over the gate and the second insulating layer;
forming a first via hole and a second via hole, each of the first via hole and the second via hole penetrating through the interlayer insulating layer, the second insulating layer, the active layer, and the first insulating layer;
forming a source electrode and a drain electrode, the source electrode and the drain electrode, respectively, filling the first via hole and the second via hole and passing through the first via hole and the second via hole to electrically couple to the active layer and the light shielding layer.

10. The method according to claim 9, wherein forming the first via hole and the second via hole comprises:
forming two first sub via holes penetrating through the interlayer insulating layer and the second insulating layer; and
forming two second sub via holes penetrating through the active layer and the first insulating layer.

11. The method of claim 9, wherein a lateral dimension of the first sub via hole is greater than a lateral dimension of the second sub via hole.

12. The method according to claim 9, wherein forming the first via hole and the second via hole comprises:
forming a patterned mask over the interlayer insulating layer;
performing a first etching process with the patterned mask to form two openings penetrating the interlayer insulating layer, the second insulating layer, the active layer, and the first insulating layer such that a part of a surface of the light shielding layer is exposed;
reducing the patterned mask to form a reduced mask; and
performing a second etching process with the reduced mask such that at least lateral dimensions of parts of the two openings above the active layer are enlarged.

13. The method according to claim 9, wherein the light shielding layer comprises amorphous silicon, the active layer comprises polysilicon, and the light shielding layer is configured to shield light to prevent the light from being incident on the active layer.

14. The method according to claim 9, wherein providing the multilayer structure including the light shielding layer, the first insulating layer, and the active layer comprises:
forming the multilayer structure over a light transmissive base layer.

15. A method of fabricating a thin film transistor, comprising:
providing a multilayer structure including a gate, a first insulating layer, and an active layer, wherein the first insulating layer is disposed between the gate and the active layer;
forming a second insulating layer covering the active layer;
forming a light shielding layer over the second insulating layer;
forming an interlayer insulating layer over the light shielding layer and the second insulating layer;
forming a first via hole and a second via hole, each of the first via hole and the second via hole penetrating through the interlayer insulating layer, the light shielding layer, and the second insulating layer to respectively expose parts of a surface of the active layer;
forming a source electrode and a drain electrode, the source electrode and the drain electrode filling the first via hole and the second via hole, respectively, and passing through the first via hole and the second via hole to electrically couple to the active layer and the light shielding layer.

16. The method according to claim 15, wherein forming the first via hole and the second via hole comprises:
forming a patterned mask over the interlayer insulating layer;
performing an etching process with the patterned mask to form the first via hole and the second via hole extending through the interlayer insulating layer, the light shielding layer, and the second insulating layer.

17. The method according to claim 15, wherein the light shielding layer comprises amorphous silicon, the active layer comprises polysilicon, and the light shielding layer is configured to shield light to prevent the light from being incident on the active layer.

18. The method according to claim 15, wherein providing the multilayer structure including the gate, the first insulating layer, and the active layer comprises:
forming the multilayer structure over a light transmissive base layer.

19. An array substrate comprising a plurality of thin film transistors according to claim 1 arranged in an array.

20. A display device comprising the array substrate of claim 19.
